(19) United States
(12) Patent Application Publication
(10) Pub. No.: US 2010/0027207 A1
(43) Pub. Date: Feb. 4, 2010

(54) ELECTRONIC DEVICE WITH DISPLAY

(75) Inventors: JI-YING JIN, Shenzhen City (CN); CHUANG YUE, Shenzhen City (CN); EN-LONG HAO, Shenzhen City (CN); WEI-RONG XIAO, Shenzhen City (CN); QIANG ZHANG, Shenzhen City (CN); LIE ZHANG, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/346,841

(22) Filed: Dec. 31, 2008

(30) Foreign Application Priority Data
Aug. 1, 2008 (CN) 200810303310.5

(51) Int. Cl. H05K 7/00

(52) U.S. Cl. 361/679.21

(57) ABSTRACT

An electronic device includes a main body and a cover. The main body includes a front surface with a display disposed thereon, a rear surface, a bottom surface, a top surface, and two opposite lateral surfaces. Each lateral surface defines a sliding slot extending substantially from the center of the lateral surface towards the bottom surface. The cover includes a cover portion and two connecting portions. The two connecting portions are located at two ends of the cover portion spatially corresponding to the sliding slots. The connecting portion includes a supporting portion and a latching portion. The supporting portion protrudes substantially perpendicularly from the cover portion. The latching portion extends into the sliding slot from the free end of the supporting portion and slidably latches with the sliding slot.

### TECHNICAL FIELD

The present disclosure relates to electronic devices and, particularly, to an electronic device with a display.

### DESCRIPTION OF THE RELATED ART

Many electronic devices utilize a display showing various types of information, such as videos, images, and others. When these electronic devices are not in use, they often make use of a cover to protect the display; further, the display often requires a support mechanism, such as a bracket, to maintain a usable orientation. The support mechanism and the display cover are discrete elements, frequently compromising efforts to reduce size and volume of the electronic device.

What is needed, therefore, is electronic device with a display cover capable of being used as a supporting mechanism to overcome the above problems.

### BRIEF DESCRIPTION OF THE DRAWINGS

Many aspects of the present electronic device can be better understood with references to the accompanying drawings. The components in the drawing are not necessarily drawn to scale, the emphasis instead being placed upon clearly illustrating the principles of the present electronic device.

FIG. 1 is a schematic, exploded view of an electronic device according to an exemplary embodiment.

FIG. 2 is a schematic view of the electronic device of FIG. 1 in a first working position.

FIG. 3 is a schematic view of the electronic device of FIG. 1 not in use.

FIG. 4 is a schematic view of the electronic device of FIG. 1 in a second working position.

### DETAILED DESCRIPTION OF THE EMBODIMENTS

Embodiments of the present disclosure will now be described in detail below, with references to the accompanying drawings.

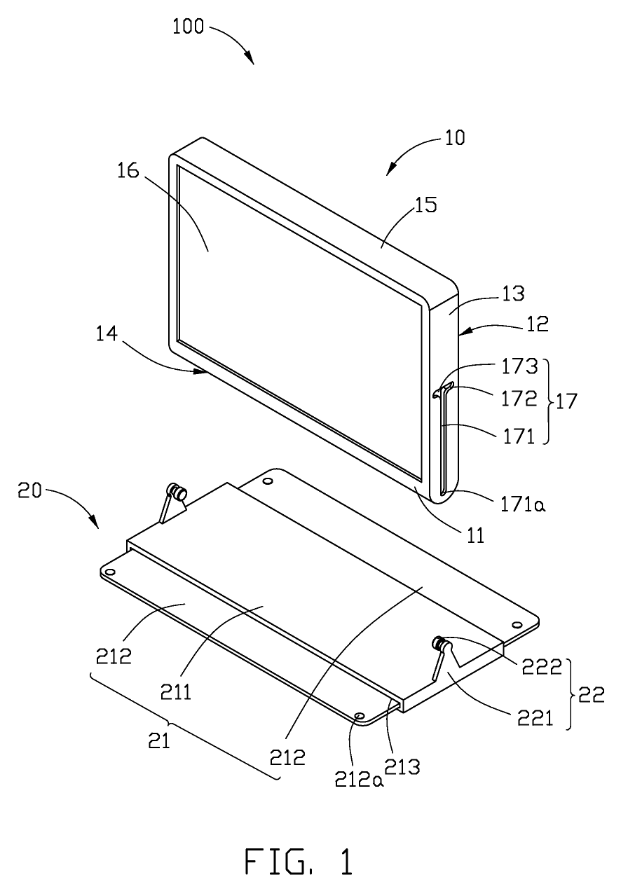

Referring to FIG. 1, an electronic device 100 according to an exemplary embodiment is shown. The electronic device 100 can be a monitor, a television, or a portable computer. The electronic device 100 includes a main body 10 and a cover 20.

In the present embodiment, the electronic device 100 is a portable computer, and the main body 10 houses components such as CPUs (not shown), motherboard (not shown) and others, thereof. The main body 10 includes a front surface 11, a rear surface 12, two opposite lateral surfaces 13, a bottom surface 14, and a top surface 15. A display 16 is disposed on the front surface 11 of the main body 10. Each lateral surface 13 defines a sliding slot 17.

In the present embodiment, the sliding slot 17 is a T-shaped slot including a main length 171, a first branch length 172, and a second branch length 173. The main length 171 extends substantially from the center of the lateral surface 13 towards the bottom surface 14, and is substantially parallel to the front surface 11 of the main body 10. The first branch length 172 and the second branch length 173 are all substantially perpendicular to the main length 171 and communicate with the main length 171. The first branch length 172 and the second branch length 173 are symmetrical about the main length 171 and thus form the T-shaped sliding slot 17. The first branch length 172 is adjacent to the display 16 and the second branch length 173 is adjacent to the rear surface 12.

The cover 20 includes a cover portion 21 and two connecting portions 22. The cover portion 21 includes a mainboard 211, and two extending sheets 212. In the present embodiment, the mainboard 211 is substantially a flattened cuboid and includes a top surface, a bottom surface, two opposite long sidewalls and two opposite short sidewalls. The two opposite long sidewalls and the two opposite short sidewalls are substantially perpendicular to the top and bottom surfaces of the mainboard 211. The long sidewalls are substantially of the same length as the main body 10. Two receiving spaces 213 are defined in the two opposite long sidewalls. The two extending sheets 212 are slidably received in the receiving spaces 213 correspondingly, and can correspondingly slide in and out of the receiving spaces 213 to increase the size of the cover portion 21. Each extending sheet 212 has a number of suction cups 212a located near the edge thereof. The suction cups 212a fix the cover portion 21 to the main body 10 when the cover portion 21 covers the display 16 of the main body 10.

The two connecting portions 22 are located at two opposite ends of the mainboard 211 spatially corresponding to the two sliding slots 17 defined on the two lateral surfaces 13 of the main body 10. Each connecting portion 22 includes a supporting portion 221 and a latching portion 222. The supporting portion 221 perpendicularly protrudes from the cover portion 21. The latching portion 222 extends out from the free end of the supporting portion 221 substantially perpendicular to the supporting portion 221, and is slidably latches in the corresponding sliding slot 17 to provide support for the main body 10 or protect the display 16 of the main body 10.

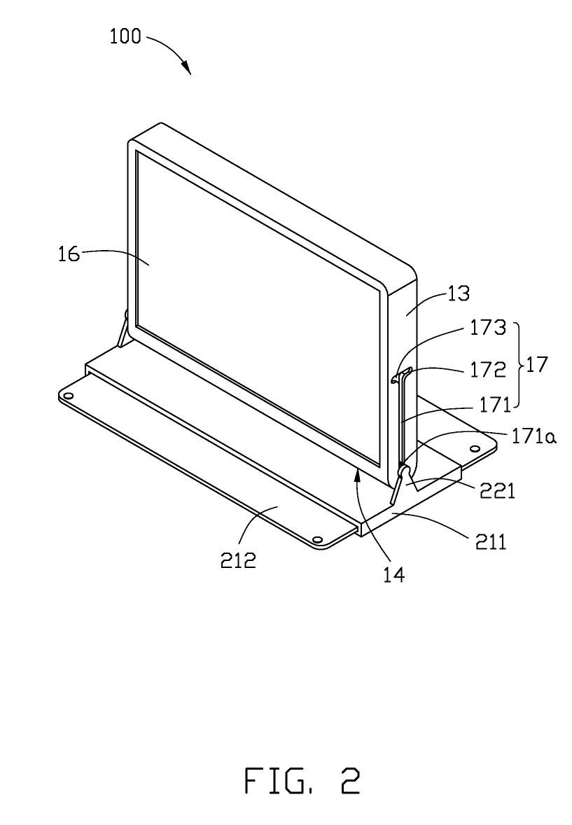

Referring to FIG. 2, when the electronic device 100 is in a first working position, the cover 20 is substantially perpendicular to the main body 10. The latching portion 222 is slidably received in the sliding slot 17, and rotatably located at a first end 171a of the main length 171 adjacent to the bottom surface 14 of the main body 10. The supporting portion 221 is taller than the distance from the first end 171a of the main length 171 to the bottom surface 14 of the main body 10, in order that the main body 10 is steadily supported by the cover 20 when the latching portion 222 is positioned at the first end 171a of the main length 171. In order that friction between the connecting portion 22 and the main body 10 when the latching portion 222 is positioned at the first end 171a of the main length 171 is sufficient to support the main body 10, the main length 171 defines a narrower first end 171a, maintaining latching portion 222 in tight contact with the sidewalls of the main length 171, or defines a shallower first end 171a to maintaining latching portion 222 in tight contact with the bottom wall of the main length 171. In the present embodiment, the first end of the main length 171 is shallower than other parts of the main length 171.

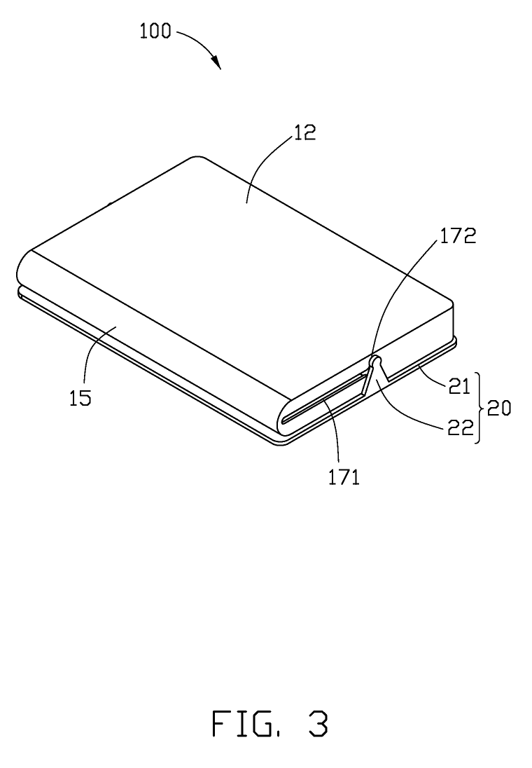

Referring to FIG. 3, the cover portion 21 of the cover 20 can provide protection for the display 16 of the main body 10 by covering the display 16 when the latching portion 222 is positioned in the first branch length 172. In the present embodiment, the connecting portion 22 is taller than the distance from the main length 171 to the front surface 11 of the main body 10. If the distance from the main length 171 to the front surface 11 of the main body 10 is substantially equal to the height of the connecting portion 22, the first branch length 172 can be omitted and the latching portion 222 positioned in a second end (not labeled) of the main length 171 away from the bottom surface 14. To steadily position the latching portion 222 in the first branch length 172, friction between the connecting portion 22 and the main body 10 when the latching portion 222 is positioned in the first branch length 172 can be increased by narrowing the first branch length 172 or decreasing the depth of the first branch length 172.

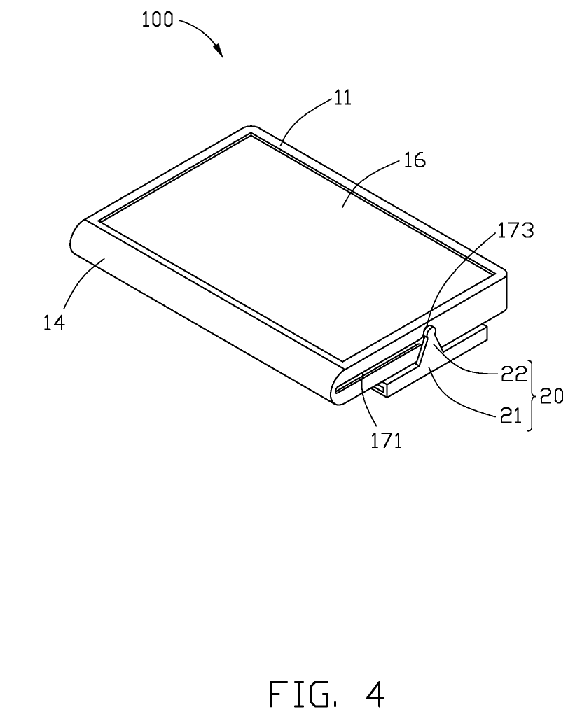

Referring to FIG. 4, the cover portion 21 of the cover 20 can be positioned substantially parallel to the main body 10 and adjacent to the rear surface 12 of the main body 10 when the latching portion 222 is positioned in the second branch length 173. It is understood that if the distance from the main length 171 to the rear surface 12 of the main body 10 is substantially equal to the height of the connecting portion 22, the second branch length 173 can be omitted and the latching portion 222 positioned in the second end of the main length 171. In order to steadily position the latching portion 222 in the second branch length 173, friction between the connecting portion 22 and the main body 10 when the latching portion 222 is positioned in the second branch length 173 can be increased by narrowing the second branch length 173 or decreasing the depth of the second branch length 173.

While certain embodiments have been described and exemplified here, various other embodiments will be apparent to those skilled in the art from the foregoing disclosure. The present disclosure is not limited to the particular embodiments described and exemplified, and the embodiments are capable of considerable variation and modification without departure from the scope of the appended claims.

What is claimed is:

1. An electronic device comprising:
a main body comprising a front surface with a display disposed thereon, a rear surface, a bottom surface, a top surface, and two opposite lateral surfaces, each lateral surface defining a sliding slot extending substantially from the center of the lateral surface towards the bottom surface; and
a cover comprising a cover portion and two connecting portions located at two ends of the cover portion spatially corresponding to the sliding slots defined on the two lateral surfaces of the main body, each connecting portion comprising:
a supporting portion protruding substantially perpendicularly from the cover portion, the supporting portion being taller than the distance from a first end of the sliding slot adjacent to the bottom surface to the bottom surface; and
a latching portion extending into the sliding slot from the free end of the supporting portion, and slidably latching with the sliding slot.

2. The electronic device as claimed in claim 1, wherein the electronic device is a monitor, a television, or a portable computer.

3. The electronic device as claimed in claim 1, wherein the cover portion comprises a mainboard, with two extending sheets connected to two opposite sides thereof.

4. The electronic device as claimed in claim 3, wherein the mainboard defines two receiving spaces on the two opposite sides thereof, in which each extending sheet is correspondingly slidable.

5. The electronic device as claimed in claim 3, wherein each extending sheet comprises a plurality of suction cups located near the edge thereof fixing the cover portion to the main body when the cover portion covers the display.

6. The electronic device as claimed in claim 1, wherein each lateral surface further defines a first branch length extending from a second end of the sliding slot away from the bottom surface, the first branch length extending substantially perpendicular to the sliding slot and towards the rear surface.

7. The electronic device as claimed in claim 1, wherein each lateral surface further defines a second branch length extending from a second end of the sliding slot away from the bottom surface, the second branch length extending substantially perpendicular to the sliding slot and towards the front surface.

8. The electronic device as claimed in claim 1, wherein each lateral surface further defines a first branch length and a second branch length extending from a second end of the sliding slot away from the bottom surface respectively, the first branch length and the second branch length extending substantially perpendicular to the sliding slot and towards the rear surface and front surface respectively.

9. The electronic device as claimed in claim 8, wherein the first branch length and the second branch length are symmetrical about the main length.

10. The electronic device as claimed in claim 1, wherein the latching portion is rotatable at the first end of the sliding slot.

11. The electronic device as claimed in claim 1, wherein the first end of the sliding slot is narrower than other portions of the sliding slot.

12. The electronic device as claimed in claim 1, wherein the first end of the sliding slot is shallower than other portions of the sliding slot.

13. An electronic device comprising:
a main body comprising a front surface with a display disposed thereon, a rear surface, a bottom surface, a top surface, and two opposite lateral surfaces, each lateral surface defining a sliding slot extending substantially from the center of the lateral surface towards the bottom surface; and
a cover portion capable of covering the display; and
two connecting portions located at two ends of the cover portion spatially corresponding to the sliding slots, each connecting portion with a first end fixed to the cover portion, and an opposite second end latching in the corresponding sliding slot and sliding along the corresponding sliding slot, the connecting portion being taller than the distance from a first end of the sliding slot adjacent to the bottom surface to the bottom surface.

14. The electronic device as claimed in claim 13, wherein the electronic device is a monitor, a television, or a portable computer.

15. The electronic device as claimed in claim 13, wherein the cover portion comprises a mainboard and two extending sheets connected to two opposite sides thereof.

16. The electronic device as claimed in claim 15, wherein the mainboard defines two receiving spaces on the two opposite sides thereof, in which each extending sheet is correspondingly slidable.

17. The electronic device as claimed in claim 15, wherein each extending sheet comprises a plurality of suction cups located near the edge thereof for fixing the cover portion to the main body when the cover portion covers the display.

18. The electronic device as claimed in claim 13, wherein each lateral surface further defines a first branch length and a second branch length extending from a second end of the sliding slot away from the bottom surface respectively, the first branch length and the second branch length being substantially perpendicular to the sliding slot and extending towards the rear surface and front surface respectively.

19. The electronic device as claimed in claim 18, wherein the first branch length and the second branch length are symmetrical about the main length.

20. The electronic device as claimed in claim 1, wherein the first end of the sliding slot is narrower or shallower than other portions of the sliding slot.
